(19) United States
(12) Patent Application Publication
(10) Pub. No.: US 2026/0328811 A1
(43) Pub. Date: Oct. 22, 2026

(54) PROBE CARD

(71) Applicant: YOKOWO CO., LTD., Tokyo (JP)

(72) Inventor: Yuki NARIZUKA, Tomioka-shi (JP)

(73) Assignee: YOKOWO CO., LTD., Tokyo (JP)

(21) Appl. No.: 19/644,592

(22) Filed: Apr. 10, 2026

(30) Foreign Application Priority Data
Apr. 17, 2025 (JP) 2025-067852

(51) Int. Cl. G01R 1/073; G01R 31/28

(52) U.S. Cl. CPC G01R 1/07364; G01R 31/2889

(57) ABSTRACT

A probe card includes an inspection substrate, a probe head that overlaps the inspection substrate, a supporter that is located on a side of the inspection substrate opposite to a side where the probe head is located, and a fastening member that extends through the inspection substrate and fastens the probe head and the supporter. The fastening member includes a plurality of members configured to be connected to each other to fasten the probe head and the supporter. The fastening member is configured to allow adjustment of a position of at least one of the members along a direction in which the fastening member extends through the inspection substrate.

### CROSS REFERENCE TO RELATED APPLICATIONS

This application is based on Japanese patent application No. 2025-067852, the content of which is incorporated hereinto by reference.

### BACKGROUND

### Technical Field

The present invention relates to a probe card.

### Related Art

In recent years, various probe cards have been developed. The probe card includes an inspection substrate and a probe head that overlaps the inspection substrate.

WO2008/114464 discloses a probe card. The probe card includes a support member, a probe substrate located on one surface side of the support member, a spacer that extends through the support member, and a screw member that extends through the spacer and is screwed to a fixing portion of the support member. The spacer has a length required to align height positions of distal ends of probes provided on the probe substrate with the same virtual plane.

### SUMMARY OF THE INVENTION

In the probe card, an inspection substrate and a supporter located on a side of the inspection substrate opposite to a side where a probe head is located may be fastened by a screw extending through the inspection substrate. When the probe head and the supporter are fastened, for example, it may be necessary to control the probe head to a desired position to suppress the probe head from warping in conformity with the inspection substrate or to match a position of a pad electrically connected to the probe of the probe head.

An example of the object of the present invention is to control a probe head to a desired position with the probe head and the supporter fastened. Other objects of the present invention will become apparent from the description of the present specification.

An aspect of the present invention is a probe card. The probe card includes an inspection substrate, a probe head that overlaps the inspection substrate, a supporter that is located on a side of the inspection substrate opposite to a side where the probe head is located, and a fastening member that extends through the inspection substrate and fastens the probe head and the supporter. The fastening member includes a plurality of members configured to be connected to each other to fasten the probe head and the supporter. The fastening member is configured to allow adjustment of a position of at least one of the members along a direction in which the fastening member extends through the inspection substrate.

According to the aspect of the present invention, the probe head can be controlled to a desired position with the probe head and the supporter fastened.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is an exploded perspective view of a probe card according to an embodiment;

FIG. 2 is an exploded perspective view of a probe head, a space transformer, and an alignment jig according to the embodiment;

FIG. 3 is an exploded perspective view of a screw plate, a bridge, and a supporter according to the embodiment;

FIG. 4 is a cross-sectional view of a probe card according to the embodiment; and

FIG. 5 is an enlarged view of a central region of FIG. 4.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, an embodiment of the present invention will be described with reference to the drawings. In all drawings, the same constituent elements are denoted by the same reference signs, and detailed description thereof will not be repeated.

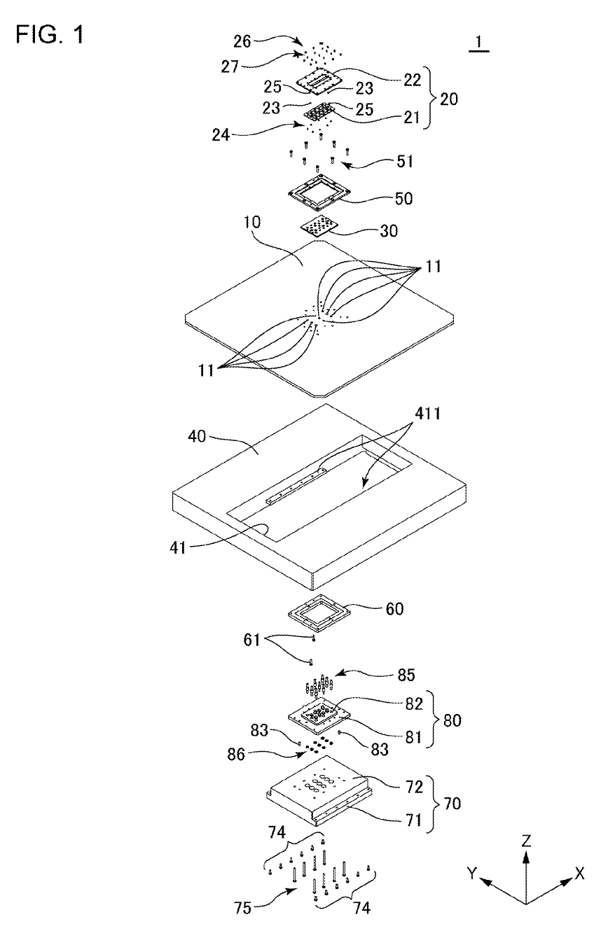

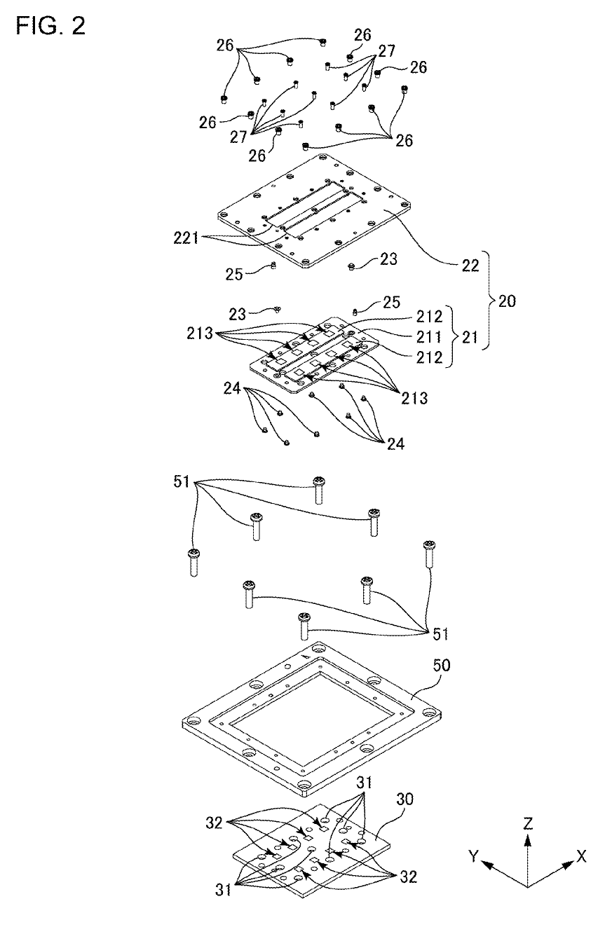

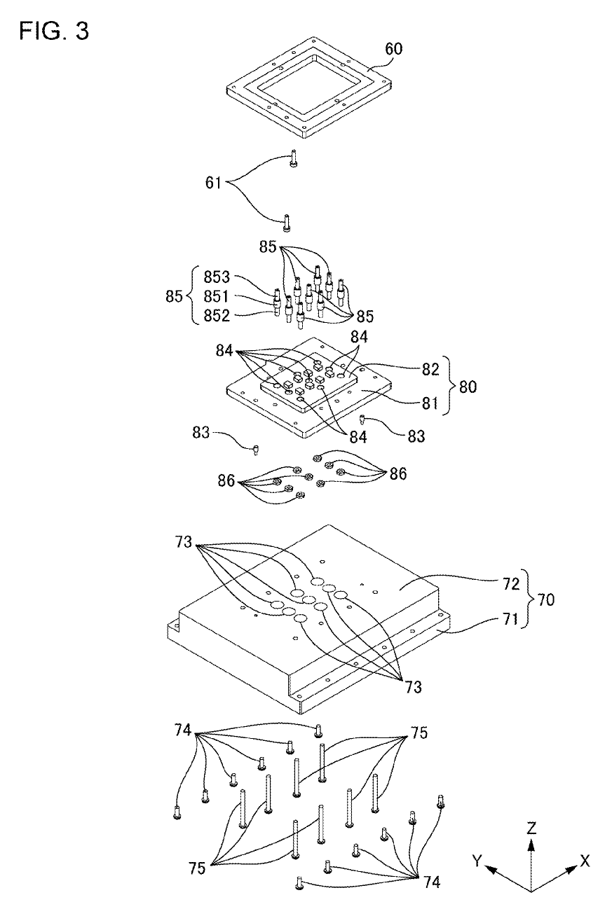

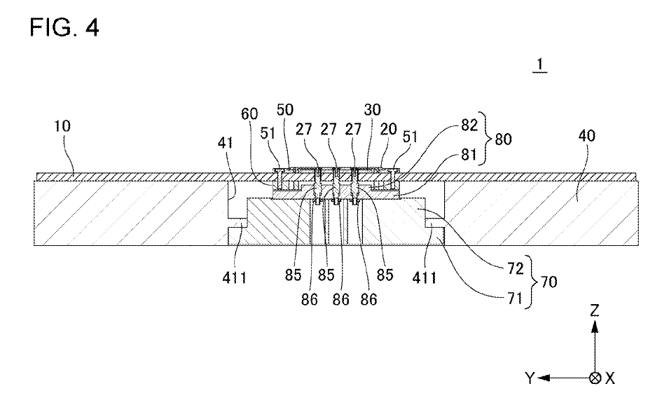

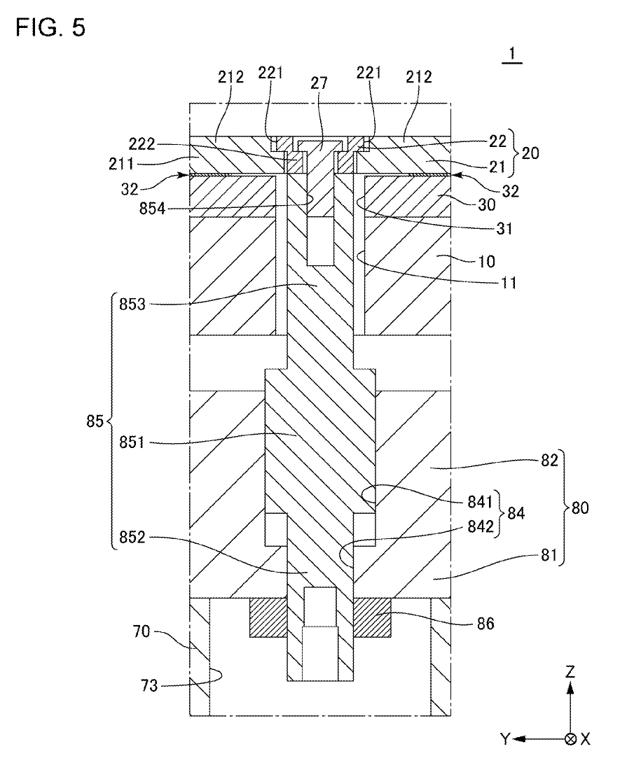

FIG. 1 is an exploded perspective view of a probe card 1 according to an embodiment. FIG. 2 is an exploded perspective view of a probe head 20, a space transformer 30, and an alignment jig 50 according to the embodiment. FIG. 3 is an exploded perspective view of a screw plate 60, a bridge 70, and a supporter 80 according to the embodiment. FIG. 4 is a cross-sectional view of a probe card 1 according to the embodiment. FIG. 5 is an enlarged view of a central region of FIG. 4. The cross-sections shown in FIGS. 4 and 5 show a cross-section of the probe card 1 according to the embodiment at substantially a center in an X direction described below.

In order to describe directions, an X direction, a Y direction, and a Z direction are defined. In each of the drawings, the X axis indicating the X direction, the Y axis indicating the Y direction, and the Z axis indicating the Z direction are shown. In FIGS. 4 and 5, the X axis indicated by the white circle with X indicates that the arrow of the X axis points to the back side of the paper plane. The Z direction is a direction parallel to a vertical direction. The X direction is one of horizontal directions perpendicular to the Z direction. The Y direction is one of the horizontal directions perpendicular to the Z direction and the X direction. In the embodiment, the Z direction is described as an up-down direction.

Hereinafter, unless otherwise specified, the +X side or +X means a side indicated by the arrow of the X axis, and the -X side or -X means a side opposite to the side indicated by the arrow of the X axis. Hereinafter, unless otherwise specified, the +Y side or +Y means a side indicated by the arrow of the Y axis, and the -Y side or -Y means a side opposite to the side indicated by the arrow of the Y axis. Hereinafter, unless otherwise specified, the +Z side or +Z means a side indicated by the arrow of the Z axis, and the -Z side or -Z means a side opposite to the side indicated by the arrow of the Z axis.

The probe card 1 according to the embodiment will be mainly described with reference to FIGS. 1 to 3. FIGS. 4 and 5 will be referred to as necessary.

As shown in FIG. 1, the probe card 1 according to the embodiment includes an inspection substrate 10, a probe head 20, a space transformer 30, a stiffener 40, an alignment jig 50, a screw plate 60, a bridge 70, and a supporter 80. In the inspection using the probe card 1, an inspection target such as a wafer is disposed on the +Z side with respect to the probe head 20.

In the embodiment, the inspection substrate 10 is a rigid substrate such as a printed circuit board (PCB). The inspection substrate 10 is disposed substantially perpendicularly to the Z direction. In the example shown in FIG. 1, the inspection substrate 10 has a substantially square shape having a pair of sides substantially parallel to the X direction and a pair of sides substantially parallel to the Y direction with the four corners cut out as viewed from the +Z side. In other words, the inspection substrate 10 has a substantially octagonal shape as viewed from the +Z side. The shape of the inspection substrate 10 is not limited to the example shown in FIG. 1. As shown in FIG. 1, substantially central regions of the inspection substrate 10 define nine first through-holes 11 corresponding to nine bosses 85 described below.

When the probe card 1 is assembled, the probe head 20 is located on the +Z side with respect to the inspection substrate 10 and overlaps the substantially central region of the inspection substrate 10. In the example shown in FIGS. 1 and 2, the probe head 20 includes a support body 21 and a frame 22. The probe head 20 may not include the frame 22.

In the example shown in FIG. 2, the support body 21 includes a plate 211 and two ridges 212. The support body 21 is composed of, for example, a pin block including a +Z side portion of the plate 211 and the two ridges 212, and a pin plate including a -Z side portion of the plate 211. The support body 21 according to the embodiment is depicted as the pin block and the pin plate being integrated. The pin block and the pin plate are composed of, for example, an insulator. The plate 211 is disposed substantially perpendicularly to the Z direction. In the example shown in FIG. 2, the plate 211 has a substantially rectangular shape having a pair of long sides substantially parallel to the X direction and a pair of short sides substantially parallel to the Y direction as viewed from the +Z side. The shape of the plate 211 is not limited to the example shown in FIG. 2. The two ridges 212 protrude from the +Z surface of the plate 211 to the +Z side. As viewed from the +Z side, the two ridges 212 are located on both sides of a center axis passing through the Y direction of the plate 211. As viewed from the +Z side, the ridges 212 extend in the X direction. The shape, number, and disposition of the ridges 212 are not limited to the example shown in FIG. 2. For example, as viewed from the +Z side, one ridge 212 may be provided only at substantially the center of the plate 211.

In the example shown in FIG. 2, four probe regions 213 are provided in each of the two ridges 212. In each of the ridges 212, the four probe regions 213 are arranged in the X direction. A plurality of probes is provided in each of the probe regions 213. The support body 21 supports the probe extending through the probe region 213. The position at which the probe is disposed is not limited to the example shown in FIG. 2.

The frame 22 is composed of, for example, a metal. The frame 22 is disposed substantially perpendicularly to the Z direction. In the examples shown in FIGS. 1 and 2, the frame 22 has a substantially quadrangular shape having a pair of sides substantially parallel to the X direction and a pair of sides substantially parallel to the Y direction. The shape of the frame 22 is not limited to the examples shown in FIGS. 1 and 2. The frame 22 defines two frame openings 221 into which the two ridges 212 of the support body 21 enter. When the two probe regions 213 are exposed from the two frame openings 221, the frame 22 covers the +Z surface of the plate 211 except for the two ridges 212. As shown in FIG. 5, the frame 22 includes protrusions 222 extending through the support body 21. The -Z surface of the frame 22 is provided with nine protrusions 222 corresponding to nine bosses 85 described below.

In the examples shown in FIGS. 1 and 2, the support body 21 and the frame 22 are positioned by two flanged pins 23. The -Z side portion of the flanged pin 23 is inserted into the plate 211. The +Z side portion of the flanged pin 23 is inserted into the frame 22. The number and disposition of the flanged pins 23 are not limited to the examples shown in FIGS. 1 and 2. The positioning pin for positioning the support body 21 and the frame 22 is not limited to the flanged pin and may be another type of pin.

In the examples shown in FIGS. 1 and 2, the support body 21 and the frame 22 are fastened to each other by eight slim head screws 24. The eight slim head screws 24 are inserted into the support body 21 and the frame 22 from the -Z side of the probe head 20. In the examples shown in FIGS. 1 and 2, the eight slim head screws 24 are disposed along an outer periphery of the plate 211. The number and disposition of the slim head screws 24 are not limited to the examples shown in FIGS. 1 and 2. The fastening member for fastening the support body 21 and the frame 22 is not limited to the slim head screw and may be another type of screw.

In the embodiment, the space transformer 30 is a substrate having an organic multilayer film such as multilayer organic (MLO (registered trademark)) or the like. The space transformer 30 may be a substrate having a ceramic multilayer film such as multilayer ceramic (MLC). When the probe card 1 is assembled, the space transformer 30 is located between the substantially central region of the inspection substrate 10 and the probe head 20. The space transformer 30 is disposed substantially perpendicularly to the Z direction. In the examples shown in FIGS. 1 and 2, the space transformer 30 has a substantially rectangular shape having a pair of long sides substantially parallel to the X direction and a pair of short sides substantially parallel to the Y direction as viewed from the +Z side. The shape of the space transformer 30 is not limited to the examples shown in FIGS. 1 and 2. As shown in FIG. 2, the space transformer 30 defines nine second through-holes 31 corresponding to nine bosses 85 described below.

In the example shown in FIG. 2, a plurality of pads 32 are provided on the +Z surface of the space transformer 30 corresponding to a plurality of probes provided in the eight probe regions 213 of the probe head 20. The inspection target and the inspection substrate 10 are electrically connected to each other via the probe and the space transformer 30 by the +Z side end part of the probe of the probe head 20 in contact with the inspection target and by the -Z side end part of the probe of the probe head 20 in contact with the pad 32. The space transformer 30 can convert a pitch of the plurality of probes of the probe head 20 and a pitch of a plurality of electrodes electrically connected to the plurality of probes of the inspection substrate 10. Specifically, the pitch of the plurality of electrodes electrically connected to the plurality of probes of the inspection substrate 10 is wider than the pitch of the plurality of probes of the probe head 20.

The stiffener 40 is composed of, for example, a metal. When the probe card 1 is assembled, the stiffener 40 is located on the -Z side with respect to the inspection substrate 10. A substantially central region of the stiffener 40 in the Y direction defines a stiffener opening 41. In the example shown in FIG. 1, the stiffener opening 41 has a substantially rectangular shape having a pair of long sides substantially parallel to the X direction and a pair of short sides substantially parallel to the Y direction as viewed from the +Z side. The shape of the stiffener opening 41 is not limited to the example shown in FIG. 1. Two flanges 411 are provided on both inner surfaces of the stiffener opening 41 facing each other in the Y direction. The inspection substrate 10 is supported by the stiffener 40 on both sides of the stiffener opening 41 in the Y direction. Therefore, the inspection substrate 10 can be reinforced by the stiffener 40.

The alignment jig 50 is composed of, for example, a metal. The alignment jig 50 is located on the +Z side with respect to the inspection substrate 10. In the examples shown in FIGS. 1 and 2, the alignment jig 50 has a substantially quadrangular frame shape having a pair of sides substantially parallel to the X direction and a pair of sides substantially parallel to the Y direction as viewed from the +Z side. When the probe card 1 is assembled, the alignment jig 50 surrounds the space transformer 30 as viewed from the +Z side.

In the examples shown in FIGS. 1 and 2, the frame 22 and the alignment jig 50 are positioned by two first stepped pins 25. The +Z side small diameter portion of the first stepped pin 25 is inserted into the frame 22. The -Z side large diameter portion of the first stepped pin 25 is inserted into the alignment jig 50. The number and disposition of the first stepped pins 25 are not limited to the examples shown in FIGS. 1 and 2. The positioning pin for positioning the frame 22 and the alignment jig 50 is not limited to the stepped pin and may be another type of pin.

In the examples shown in FIGS. 1 and 2, the frame 22 and the alignment jig 50 are fastened by twelve medium diameter pan head screws 26. The medium diameter pan head screws 26 are inserted into an outer peripheral region of the frame 22 and an inner peripheral region of the alignment jig 50 from the +Z side of the frame 22. In the examples shown in FIGS. 1 and 2, the twelve medium diameter pan head screws 26 are disposed along the outer periphery of the frame 22. The number and disposition of the medium diameter pan head screws 26 are not limited to the examples shown in FIGS. 1 and 2. The fastening member for fastening the frame 22 and the alignment jig 50 is not limited to the pan head screw and may be another type of screw.

The screw plate 60 is composed of, for example, a metal. When the probe card 1 is assembled, the screw plate 60 is located on the -Z side with respect to the inspection substrate 10. In the examples shown in FIGS. 1 and 3, the screw plate 60 has a substantially quadrangular frame shape having a pair of sides substantially parallel to the X direction and a pair of sides substantially parallel to the Y direction as viewed from the +Z side. As can be seen from FIG. 4, when the probe card 1 is assembled, the screw plate 60 is located inside the stiffener opening 41.

In the examples shown in FIGS. 1 to 3, the inspection substrate 10, the alignment jig 50, and the screw plate 60 are positioned by two headed pins 61. The headed pins 61 are inserted into the screw plate 60, the inspection substrate 10, and the alignment jig 50 from the -Z side of the screw plate 60. The -Z side head portion of the headed pin 61 enters the screw plate 60. The number and disposition of the headed pins 61 are not limited to the examples shown in FIGS. 1 to 3. The positioning pin for positioning the inspection substrate 10, the alignment jig 50, and the screw plate 60 is not limited to the headed pin and may be another type of pin.

In the examples shown in FIGS. 1 to 3, the inspection substrate 10, the alignment jig 50, and the screw plate 60 are fastened by eight large diameter pan head screws 51. The large diameter pan head screws 51 are inserted into the alignment jig 50, the inspection substrate 10, and the screw plate 60 from the +Z side of the alignment jig 50. In the examples shown in FIGS. 1 to 3, the eight large diameter pan head screws 51 are disposed along the outer periphery of the alignment jig 50. The number and disposition of the large diameter pan head screws 51 are not limited to the examples shown in FIGS. 1 to 3. The fastening member for fastening the inspection substrate 10, the alignment jig 50, and the screw plate 60 is not limited to the pan head screw and may be another type of screw.

The bridge 70 is composed of, for example, metal. The bridge 70 includes a first bridge base 71 and a second bridge base 72. As viewed from the +Z side, the first bridge base 71 has a substantially quadrangular shape having a pair of sides substantially parallel to the X direction and a pair of sides substantially parallel to the Y direction. The second bridge base 72 protrudes from the +Z surface of the first bridge base 71 to the +Z side. As viewed from the +Z side, the second bridge base 72 has a substantially quadrangular shape having a pair of sides substantially parallel to the X direction and a pair of sides substantially parallel to the Y direction. The dimension of the first bridge base 71 in the X direction and the dimension of the second bridge base 72 in the X direction are equal to each other. The dimension of the second bridge base 72 in the Y direction is less than the dimension of the first bridge base 71 in the Y direction such that both end portions of the first bridge base 71 in the Y direction protrude from both surfaces of the second bridge base 72 in the Y direction as viewed from the +Z side. The first bridge base 71 and the second bridge base 72 are provided with nine third through-holes 73 corresponding to nine bosses 85 described below.

As can be seen from FIG. 4, when the probe card 1 is assembled, the bridge 70 is located inside the stiffener opening 41. In the examples shown in FIGS. 1 and 3, the pair of stiffeners 40 and the bridge 70 are fastened to each other by twelve short screws 74. The short screws 74 are inserted into both end portions of the first bridge base 71 in the Y direction and the pair of flanges 411 from the -Z side of the bridge 70. The number and disposition of the short screws 74 are not limited to the examples shown in FIGS. 1 and 3. The fastening member for fastening the stiffener 40 and the bridge 70 is not limited to the short screw and may be another type of screw.

The supporter 80 is composed of, for example, a metal. The supporter 80 includes a first supporter base 81 and a second supporter base 82. As viewed from the +Z side, the first supporter base 81 has a substantially quadrangular shape having a pair of sides substantially parallel to the X direction and a pair of sides substantially parallel to the Y direction. The second supporter base 82 protrudes from a substantially central region of the +Z surface of the first supporter base 81 to the +Z side. As viewed from the +Z side, the second supporter base 82 has a substantially quadrangular shape having a pair of sides substantially parallel to the X direction and a pair of sides substantially parallel to the Y direction.

As can be seen from FIG. 4, when the probe card 1 is assembled, the supporter 80 is located between the inspection substrate 10 and the bridge 70, and the second supporter base 82 is surrounded by the screw plate 60.

In the examples shown in FIGS. 1 and 3, the bridge 70 and the supporter 80 are positioned by two second stepped pins 83. The +Z side large diameter portion of the second stepped pin 83 is inserted into the first supporter base 81. The -Z side small diameter portion of the second stepped pin 83 is inserted into the second bridge base 72. The number and position of the second stepped pins 83 are not limited to the examples shown in FIGS. 1 and 3. The positioning pin for positioning the bridge 70 and the supporter 80 is not limited to the stepped pin and may be another type of pin.

In the examples shown in FIGS. 1 and 3, the bridge 70 and the supporter 80 are fastened to each other by eight long screws 75. The long screws 75 are inserted into the first bridge base 71, the second bridge base 72, and the first supporter base 81 from the -Z side of the bridge 70. In the examples shown in FIGS. 1 and 3, the eight long screws 75 are disposed along the +Y side and the -Y side of the first supporter base 81. The number and position of the long screws 75 are not limited to the examples shown in FIGS. 1 and 3. The fastening member for fastening the bridge 70 and the supporter 80 is not limited to the long screw and may be another type of screw.

As shown in FIG. 3, the supporter 80 is provided with nine fourth through-holes 84. As viewed from the +Z side, the nine fourth through-holes 84 are disposed in three rows in the X direction and three columns in the Y direction in substantially central regions of the first supporter base 81 and the second supporter base 82. As shown in FIG. 5, the fourth through-hole 84 includes a large-diameter hole 841 and a small-diameter hole 842. The +Z side end part of the large-diameter hole 841 is open from the +Z surface of the second supporter base 82. The -Z side end part of the large-diameter hole 841 and the +Z side end part of the small-diameter hole 842 communicate with each other. The -Z side end part of the small-diameter hole 842 is open from the -Z surface of the first supporter base 81. The large-diameter hole 841 and the small-diameter hole 842 have the same center axis and extend in the Z direction. The diameter of the small-diameter hole 842 in the horizontal direction is less than the diameter of the large-diameter hole 841 in the horizontal direction.

As can be seen from FIG. 3, nine bosses 85 are inserted into the nine fourth through-holes 84. The number and position of the fourth through-holes 84 and the bosses 85 are not limited to the examples shown in FIGS. 1 and 3. As shown in FIGS. 3 and 5, the boss 85 includes a large-diameter shaft 851, a first small-diameter shaft 852, and a second small-diameter shaft 853. The large-diameter shaft 851, the first small-diameter shaft 852, and the second small-diameter shaft 853 have the same center axis and extend in the Z direction. The diameters of the first small-diameter shaft 852 and the second small-diameter shaft 853 in the horizontal direction are less than the diameter of the large-diameter shaft 851 in the horizontal direction. As shown in FIG. 5, when the probe card 1 is assembled, the large-diameter shaft 851 is inserted into the large-diameter hole 841. The first small-diameter shaft 852 is provided at the -Z side end part of the large-diameter shaft 851. When the probe card 1 is assembled, the first small-diameter shaft 852 is inserted into the small-diameter hole 842. The second small-diameter shaft 853 is provided at the +Z side end part of the large-diameter shaft 851. When the probe card 1 is assembled, the second small-diameter shaft 853 extends through the first through-hole 11 of the inspection substrate 10 and the second through-hole 31 of the space transformer 30.

The probe card 1 according to the embodiment will be further described with reference to FIG. 5. FIGS. 1 to 4 will be referred to as necessary.

The inner peripheral surface of the small-diameter hole 842 and the outer peripheral surface of the first small-diameter shaft 852 have thread ridges that engage with each other. Therefore, the small-diameter hole 842 and the first small-diameter shaft 852 can be screwed to each other. Accordingly, the boss 85 is configured to allow adjustment of the position of the boss 85 along the Z direction by rotating the first small-diameter shaft 852 around the center axis of the boss 85 with the thread ridges of the inner peripheral surface of the small-diameter hole 842 and the thread ridges of the outer peripheral surface of the first small-diameter shaft 852 engaged with each other. For example, the boss 85 can be moved to the -Z side by rotating the first small-diameter shaft 852 clockwise as viewed from the +Z side, and the boss 85 can be moved to the +Z side by rotating the first small-diameter shaft 852 counterclockwise as viewed from the +Z side. Therefore, the position of the boss 85 in the Z direction can be easily adjusted as compared to a case in which the boss 85 is simply inserted into the supporter 80.

The attachment of the supporter 80 and the boss 85 is not limited to the screwing of the small-diameter hole 842 and the first small-diameter shaft 852. In another example, an entire axis corresponding to the large-diameter shaft 851 and the first small-diameter shaft 852 of the embodiment may have a substantially same diameter regardless of a position in the Z direction, and an entire hole corresponding to the large-diameter hole 841 and the small-diameter hole 842 of the embodiment may also have a substantially same diameter regardless of a position in the Z direction, corresponding to the axis of the boss 85. The axis of the boss 85 has, for example, a diameter equal to a diameter of the large-diameter shaft 851 of the embodiment in the horizontal direction or a diameter of the first small-diameter shaft 852 of the embodiment in the horizontal direction. The fourth through-hole 84 has, for example, a diameter equal to a diameter of the large-diameter hole 841 of the embodiment in the horizontal direction or a diameter of the small-diameter hole 842 of the embodiment in the horizontal direction. In the other example, the inner peripheral surface of the fourth through-hole 84 and the outer peripheral surface of the axis of the boss 85 may have thread ridges that engage with each other. In the other example, the inner peripheral surface of the fourth through-hole 84 and the outer peripheral surface of the axis of the boss 85 can be screwed to each other. Therefore, in the other example, the boss 85 is configured to allow adjustment of the position of the boss 85 along the Z direction by rotating the axis of the boss 85 around the center axis of the boss 85 with the thread ridges of the inner peripheral surface of the fourth through-hole 84 and the thread ridges of the outer peripheral surface of the axis of the boss 85 engaged with each other. In the other example, the diameter of the second small-diameter shaft 853 in the horizontal direction may be equal to or different from the diameter of the axis corresponding to the large-diameter shaft 851 and the first small-diameter shaft 852 of the embodiment in the horizontal direction. The attachment of the supporter 80 and the boss 85 is not limited to the screwing of the supporter 80 and the boss 85 and may be another method of making the boss 85 movable in the Z direction with respect to the supporter 80.

As shown in FIG. 5, in the third through-hole 73, the first small-diameter shaft 852 is inserted into the nut 86. The outer peripheral surface of the first small-diameter shaft 852 and the inner peripheral surface of the nut 86 have thread ridges that engage with each other. Accordingly, the position of the boss 85 in the Z direction can be fixed by screwing the first small-diameter shaft 852 and the nut 86 to each other with the -Z surface of the first supporter base 81 and the +Z surface of the nut 86 in contact with each other. Therefore, the nut 86 is a fixing member that fixes the position of the boss 85 in the Z direction. Accordingly, the fluctuation of the boss 85 in the Z direction from the desired position can be suppressed as compared to a case in which the first small-diameter shaft 852 and the nut 86 are not screwed to each other.

As can be seen from FIGS. 1 to 3, the probe head 20 and the nine bosses 85 are fastened to each other by nine small diameter pan head screws 27. As shown in FIG. 5, the small diameter pan head screw 27 extends through the protrusion 222 from the +Z side of the frame 22 and is inserted into a tapped hole 854 on the +Z side of the second small-diameter shaft 853. The outer peripheral surface of the small diameter pan head screw 27 and the inner peripheral surface of the tapped hole 854 have thread ridges that engage with each other. Therefore, the small diameter pan head screw 27 and the boss 85 are connected to each other by screwing the small diameter pan head screw 27 and the second small-diameter shaft 853, to fasten the frame 22 and the boss 85 to each other. The fastening member for fastening the probe head 20 and the boss 85 is not limited to the pan head screw and may be another type of screw.

The tightening torque of the nut 86 is greater than the tightening torque of the small diameter pan head screw 27. Therefore, the nut 86 does not rotate even if the force for tightening the small diameter pan head screw 27 is exerted to the small diameter pan head screw 27 to exert the force for rotating the boss 85. Further, the small diameter pan head screw 27 is tightened by rotating the small diameter pan head screw 27 clockwise as viewed from the +Z side. The nut 86, on the other hand, is tightened by rotating the nut 86 clockwise as viewed from the -Z side. Therefore, the nut 86 is not loosened even if the force for tightening the small diameter pan head screw 27 is exerted to the small diameter pan head screw 27 to exert the force for rotating the boss 85.

In the embodiment, the boss 85 and the small diameter pan head screw 27 are fastening members configured such that the boss 85 and the small diameter pan head screw 27 are connected to each other to extend through the inspection substrate 10 and the space transformer 30 and fasten the probe head 20 and the supporter 80. That is, in the embodiment, the Z direction is a direction in which the boss 85 and the small diameter pan head screw 27 extends through the inspection substrate 10 and the probe head 20. As can be seen from FIGS. 1 to 3, the nine bosses 85 and the nine small diameter pan head screws 27 are provided in a substantially central region of the probe head 20. A plurality of probes is provided in the eight probe regions 213 of the substantially central region of the probe head 20. In the inspection using the probe card 1, a relatively large force is likely to be applied to the substantially central region of the probe head 20 via the plurality of probes. This force may be a factor in deforming the substantially central region of the probe head 20. In the embodiment, the deformation of the substantially central region of the probe head 20 can be suppressed by fastening the probe head 20 and the supporter 80 to each other by the boss 85 and the small diameter pan head screw 27.

In the embodiment, the Z-direction fastening positions of the boss 85 and the small diameter pan head screw 27 can be controlled to the desired positions by adjusting the position of the boss 85 along the Z direction. By controlling the Z-direction fastening positions of the boss 85 and the small diameter pan head screw 27, the probe head 20 can be controlled to the desired position with the probe head 20 and the supporter 80 fastened. Therefore, the probe head 20 can be disposed at an appropriate position such that the probe head 20 can be suppressed from warping in conformity with the warpage of the inspection substrate 10 and the space transformer 30. Further, the probe head 20 can be disposed at an appropriate position in accordance with the Z-direction position of the pad 32 electrically connected to the probe of the probe head 20.

Specifically, the inspection substrate 10 may be warped due to a factor such as a manufacturing condition of the inspection substrate 10. When the inspection substrate 10 is warped, the space transformer 30 may also be warped in conformity with the inspection substrate 10. When the probe head 20 and the supporter 80 are fastened by the screw extending through the inspection substrate 10 with the inspection substrate 10 and the space transformer 30 warped, the probe head 20 may be warped in conformity with the warpage of the inspection substrate 10. When the probe head 20 is warped, the contact force between the inspection target and the +Z side end part of the probe of the probe head 20 may vary depending on the position of the probe head 20, or the +Z side end part of at least a part of the probe of the probe head 20 may not be in contact with the inspection target. However, in the embodiment, the position of the boss 85 in the Z direction can be adjusted regardless of the warpage of the inspection substrate 10 and the space transformer 30 by rotating the first small-diameter shaft 852 around the center axis of the boss 85. Therefore, in the embodiment, the probe head 20 can be controlled to the desired position with the probe head 20 and the supporter 80 fastened regardless of the warpage of the inspection substrate 10 and the space transformer 30 by adjusting the position of the boss 85 along the Z direction. For example, the probe head 20 can be aligned with a plane perpendicular to the Z direction along the supporter 80. By aligning the probe head 20 with the plane perpendicular to the Z direction, the contact force between the inspection target and the +Z side end part of the probe of the probe head 20 can be made uniform over the entire probe head 20.

Further, the Z-direction position of the pad 32 may vary depending on the position of the space transformer 30. If the probe head 20 is simply disposed without being matched to the Z-direction position of the pad 32, the contact force between the pad 32 and the -Z side end part of the probe of the probe head 20 may vary depending on the position of the probe head 20, or the -Z side end part of at least a part of the probe of the probe head 20 may not be in contact with the pad 32. However, in the embodiment, the position of the boss 85 in the Z direction can be adjusted in accordance with the Z-direction position of the pad 32. Therefore, the probe head 20 can be disposed at an appropriate position in accordance with the Z-direction position of the pad 32. Further, in the example shown in FIG. 5, the -Z surface of the protrusion 222 and the +Z surface of the second small-diameter shaft 853 are in contact with each other. Therefore, the position of the -Z surface of the protrusion 222 can be controlled by the position of the +Z surface of the second small-diameter shaft 853. For example, the position of the +Z surface of the second small-diameter shaft 853 and the position of the +Z surface of the pad 32 can be aligned with substantially the same surface. The position of the probe head 20 in the Z direction can be controlled by controlling the position of the -Z surface of the protrusion 222 in accordance with the position of the +Z surface of the second small-diameter shaft 853. The preload of the probe of the probe head 20 can be controlled by controlling the position of the probe head 20 in the Z direction.

In the embodiment, with the probe head 20 and the supporter 80 fastened, the probe head 20 is controlled to the desired position by adjusting the position of the boss 85 along the Z direction. Therefore, the probe head 20 can be controlled to the desired position without replacing the boss 85. Therefore, the mass productivity of the probe card 1 can be improved as compared to a case in which it is necessary to replace the fastening member for fastening the probe head 20 and the supporter 80.

As shown in FIG. 5, in the embodiment, the small diameter pan head screw 27 extends through the protrusion 222 and is attached to the second small-diameter shaft 853. Therefore, in the embodiment, the length of the small diameter pan head screw 27 in the Z direction can be shortened as compared to a case in which the probe head 20 and the supporter 80 are fastened to each other by the screw without using the boss 85. Furthermore, the probe head 20 can be attached and detached by attaching and detaching the small diameter pan head screw 27 on the +Z side where the probe head 20 is located with the probe head 20 directed upward in the vertical direction, to easily perform the attachment and detachment of the probe head 20. Therefore, the maintenance of the probe card 1 can be easily performed.

In the embodiment, the load of the probe head 20 can be received by the boss 85. The diameter of the boss 85 in the horizontal direction is likely to be greater than the diameter of the screw in the horizontal direction. Therefore, in the embodiment, the load-bearing capacity of the boss 85 can be increased as compared to a case in which the probe head 20 and the supporter 80 are fastened to each other by the screw without using the boss 85.

Hereinabove, the embodiments of the present invention have been described with reference to the drawings. However, the embodiment is merely an example of the present invention, and various configurations other than the above-described configurations can also be adopted.

In the embodiment, the boss 85 movable in the Z direction is attached to the supporter 80. In another example, a movable member corresponding to the boss 85 may be attached to the probe head 20. In the other example, the movable member attached to the probe head 20 and a member such as a screw extending through the supporter 80 are connected to each other to fasten the probe head 20 and the supporter 80. The probe head 20 can be controlled to the desired position by adjusting the position of the movable member attached to the probe head 20 along the Z direction.

According to the present invention, the following aspects of the probe card are provided.

### Aspect 1

In aspect 1, a probe card includes an inspection substrate, a probe head that overlaps the inspection substrate, a supporter that is located on a side of the inspection substrate opposite to a side where the probe head is located, and a fastening member that extends through the inspection substrate and fastens the probe head and the supporter. The fastening member includes a plurality of members configured to be connected to each other to fasten the probe head and the supporter. The fastening member is configured to allow adjustment of a position of at least one of the members along a direction in which the fastening member extends through the inspection substrate.

The "fastening member" corresponds to the "small diameter pan head screw" and the "boss" of the embodiment described above.

According to the above aspect, adjusting the position of at least one member allows controlling the probe head to the desired position with the probe head and the supporter fastened. Therefore, the probe head can be disposed at an appropriate position such that the probe head can be suppressed from warping in conformity with the warpage of the inspection substrate. Further, the probe head can be disposed at an appropriate position in accordance with the position of the pad electrically connected to the probe of the probe head.

### Aspect 2

In aspect 2, the fastening member is configured to allow adjustment of the position of the at least one member by rotating the at least one member.

According to the above aspect, the position of the at least one member can be easily adjusted as compared to a case in which the at least one member is simply inserted into the supporter.

### Aspect 3

In aspect 3, at least one other of the members extends through the probe head and is connected to the at least one member.

According to the above aspect, the length of the at least one other of the members can be shortened as compared to a case in which the probe head and the supporter are fastened to each other by a single screw. Further, the attachment and detachment of the probe head can be performed by attaching and detaching the at least one other of the members on the side where the probe head is located, thereby to easily perform the attachment and detachment of the probe head. Therefore, the maintenance of the probe card can be easily performed.

### Aspect 4

In aspect 4, the probe card further includes a fixing member that fixes the position of the at least one member.

The "fixing member" corresponds to the "nut" of the embodiment described above.

According to the above aspect, the fluctuation of the at least one member from the desired position can be suppressed as compared to a case in which the position of the at least one member is not fixed by the fixing member.

It is apparent that the present invention is not limited to the above embodiment, and may be modified and changed without departing from the scope and spirit of the invention.

### REFERENCE NUMERALS

1 probe card, 10 inspection substrate, 11 first through-hole, 20 probe head, 21 support body, 211 plate, 212 ridge, 213 probe region, 22 frame, 221 frame opening, 222 protrusion, 23 flanged pin, 24 slim head screw, 25 first stepped pin, 26 medium diameter pan head screw, 27 small diameter pan head screw, 30 space transformer, 31 second through-hole, 32 pad, 40 stiffener, 41 stiffener opening, 411 flange, 50 alignment jig, 51 large diameter pan head screw, 60 screw plate, 61 headed pin, 70 bridge, 71 first bridge base, 72 second bridge base, 73 third through-hole, 74 short screw, 75 long screw, 80 supporter, 81 first supporter base, 82 second supporter base, 83 second stepped pin, 84 fourth through-hole, 841 large-diameter hole, 842 small-diameter hole, 85 boss, 851 large-diameter shaft, 852 first small-diameter shaft, 853 second small-diameter shaft, 854 tapped hole, 86 nut

What is claimed is:

1. A probe card comprising:
an inspection substrate;
a probe head that overlaps the inspection substrate;
a supporter that is located on a side of the inspection substrate opposite to a side where the probe head is located; and
a fastening member that extends through the inspection substrate and fastens the probe head and the supporter,
wherein the fastening member includes a plurality of members configured to be connected to each other to fasten the probe head and the supporter, and
wherein the fastening member is configured to allow adjustment of a position of at least one of the members along a direction in which the fastening member extends through the inspection substrate.

2. The probe card according to claim 1, wherein the fastening member is configured to allow adjustment of the position of the at least one member by rotating the at least one member.

3. The probe card according to claim 1, wherein at least one other of the members extends through the probe head and is connected to the at least one member.

4. The probe card according to claim 1, further comprising a fixing member that fixes the position of the at least one member.
